(19) United States
(12) Patent Application Publication
(10) Pub. No.: US 2022/0391038 A1
(43) Pub. Date: Dec. 8, 2022

(54) CIRCUIT DESIGN AND TOUCH PANEL

(71) Applicant: TPK Touch Systems (Xiamen) Inc., Xiamen (CN)

(72) Inventors: Jun-Jie Zheng, Quanzhou City (CN); Yan-Jun Xie, Xiamen City (CN); Jun-Ping Yang, Longhai City (CN); Qing-Wen Hong, Xiamen City (CN); Liu-Kun Wu, Xiamen City (CN)

(21) Appl. No.: 17/337,791

(22) Filed: Jun. 3, 2021

(51) Int. Cl. G06F 3/044; G02F 1/1333; G06F 3/041

(52) U.S. Cl. CPC G06F 3/0443; G02F 1/13338; G06F 3/0412; G06F 2203/04112

(57) ABSTRACT

A circuit design includes a flexible film, an electrode pattern, and a connecting circuit. The flexible film has a visible area and a bending area and includes an external conductive connection. The electrode pattern is disposed in the visible area of the flexible film. The connecting circuit is electrically connected to the electrode pattern and disposed in the bending area of the flexible film. The bending area has a first portion and a second portion. The first portion is located between the visible area and the second portion. A width of one end of the second portion connected to the first portion is smaller than a width of the first portion. The external conductive connection is electrically connected to the connecting circuit and located at another end of the second portion.

### BACKGROUND

### Field of Disclosure

The present disclosure relates to a circuit design and a touch panel.

### Description of Related Art

Today's demand for smart phones, tablet computers, and other terminals has stimulated the development of touch technology towards thin thickness, narrow bezels, and low-cost products. At present, there are various products with narrow borders on the market, in which the width of the borders depends on the width and spacing of the metal wires. The line width obtained by general screen printing technology is about 60-80 microns, the line width obtained by gravure printing technology is about 30-50 microns, the line width obtained by silver printing technology is about 20-30 microns, and the line width obtained by the most common yellow light etching process is 15 microns. However, the formed thin metal wires are also prone to problems of poor adhesion and peeling.

On the other hand, based on the flexibility of the flexible film, using the flexible film and bending the flexible film to the back of the product can also greatly reduce the width of the borders. However, the problems of circuit breakage and the wire joint (such as a conductive pad) falling off easily occur during the bending process of the flexible film, resulting in poor product yields.

### SUMMARY

In view of this, one goal of the present disclosure is to provide a circuit design and a touch panel capable of addressing the aforementioned issues.

One aspect of the present disclosure is to provide a circuit design including a flexible film, an electrode pattern, and a connecting circuit. The flexible film has a visible area and a bending area and includes an external conductive connection. The electrode pattern is disposed in the visible area of the flexible film. The connecting circuit is electrically connected to the electrode pattern and disposed in the bending area of the flexible film. The bending area has a first portion and a second portion, and the first portion is located between the visible area and the second portion. A width of one end of the second portion connected to the first portion is smaller than a width of the first portion. The external conductive connection is electrically connected to the connecting circuit and located at another end of the second portion.

According to one embodiment of the present disclosure, each of the electrode pattern, the connecting circuit, and the external conductive connection independently includes a silver nanowire.

According to one embodiment of the present disclosure, the connecting circuit is a mesh channel.

According to one embodiment of the present disclosure, the connecting circuit includes a first sub-circuit and a second sub-circuit disposed side by side.

According to one embodiment of the present disclosure, each of the first sub-circuit and the second sub-circuit independently is a mesh channel.

Another aspect of the present disclosure is to provide a circuit design including a flexible film, an electrode pattern, and a connecting circuit. The flexible film has a visible area and a bending area. The electrode pattern is disposed in the visible area of the flexible film. The connecting circuit is electrically connected to the electrode pattern and disposed in the bending area of the flexible film. The connecting circuit is straight.

According to one embodiment of the present disclosure, each of the electrode pattern and the connecting circuit independently includes a silver nanowire.

According to one embodiment of the present disclosure, the circuit design further includes a flexible printed circuit board disposed away from one end of the bending area of the flexible film and electrically connected to the connecting circuit.

According to one embodiment of the present disclosure, the electrode pattern extends to the bending area.

According to one embodiment of the present disclosure, the circuit design further includes a silver paste pad disposed between the electrode pattern and the connecting circuit and in direct contact with the electrode pattern and the connecting circuit.

According to one embodiment of the present disclosure, the connecting circuit is a mesh channel.

According to one embodiment of the present disclosure, the connecting circuit comprises a first sub-circuit and a second sub-circuit disposed side by side.

According to one embodiment of the present disclosure, each of the first sub-circuit and the second sub-circuit independently is a mesh channel.

Yet another aspect of the present disclosure is to provide a circuit design including a flexible film, an electrode pattern, and a connecting circuit. The flexible film has a visible area and a bending area. The electrode pattern is disposed in the visible area of the flexible film. The connecting circuit is electrically connected to the electrode pattern and disposed in the bending area of the flexible film. The connecting circuit has a circuit pattern that is the same as the electrode pattern.

According to one embodiment of the present disclosure, each of the electrode pattern and the connecting circuit independently includes a silver nanowire.

According to one embodiment of the present disclosure, the circuit design further includes a flexible printed circuit board disposed away from one end of the bending area of the flexible film and electrically connected to the connecting circuit.

Yet another aspect of the present disclosure is to provide a touch panel including a liquid crystal display module, the aforementioned circuit design, a transparent cover, and a circuit board. The circuit design is disposed over the liquid crystal display module. The transparent cover is disposed over the circuit design. The circuit board is disposed below the liquid crystal display module. The bending area of the flexible film of the circuit design is bent downward, and the circuit design is electrically connected to the circuit board.

### BRIEF DESCRIPTION OF THE DRAWINGS

The disclosure can be more fully understood by reading the following detailed description of the embodiment, with reference made to the accompanying drawings as follows.

FIG. 1 illustrates a schematic cross-section view of a touch panel according to one comparative example of the present disclosure, in which a flexible film is not bent.

FIG. 2 illustrates a schematic top view of a circuit design according to one comparative example of the present disclosure.

FIG. 3 illustrates a cross-section schematic view of a touch panel according to one comparative example of the present disclosure, in which a flexible film has been bent.

FIG. 4 illustrates a schematic top view of a circuit design according to one embodiment of the present disclosure.

FIG. 5 illustrates a schematic top view of a circuit design according to one embodiment of the present disclosure.

FIG. 6 illustrates a schematic top view of a circuit design according to one embodiment of the present disclosure.

FIG. 7 illustrates a schematic top view of a circuit design according to one embodiment of the present disclosure.

FIG. 8 illustrates a schematic top view of a circuit design according to one embodiment of the present disclosure.

FIG. 9 illustrates a schematic top view of a circuit design according to one embodiment of the present disclosure.

FIG. 10 illustrates a schematic top view of a circuit design according to one embodiment of the present disclosure.

FIG. 11 illustrates a schematic top view of a circuit design according to one embodiment of the present disclosure.

FIG. 12 illustrates a cross-section schematic view of a touch panel according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. The embodiments disclosed below may be combined or substituted with each other under beneficial circumstances, and other embodiments may also be added to an embodiment without further description.

It will be understood that, although the terms “first,” “second,” “third,” etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present disclosure.

In the following description, certain specific details are set forth in order to provide a thorough understanding of various embodiments of the disclosure. However, one skilled in the art will understand that the disclosure may be practiced without these specific details. Furthermore, for simplifying the drawings, some of the conventional structures and elements are shown with schematic illustrations.

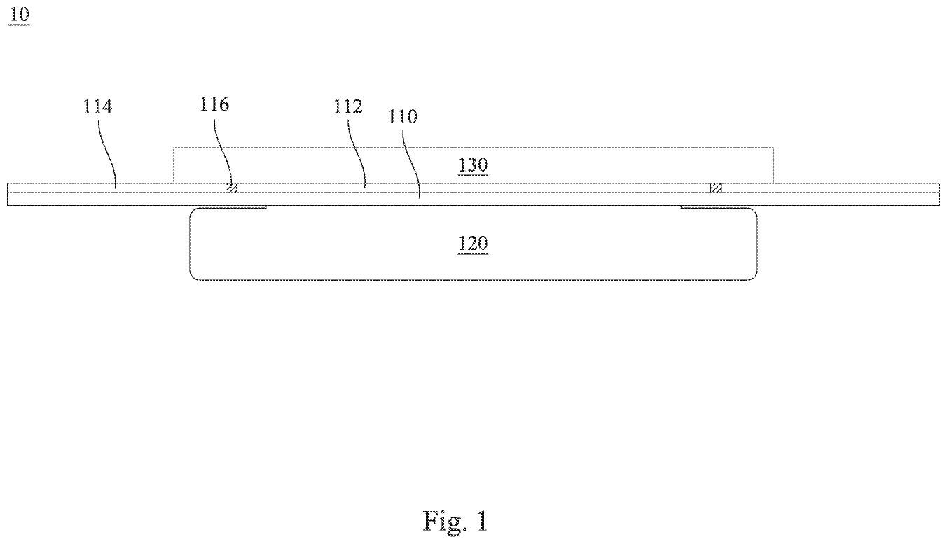

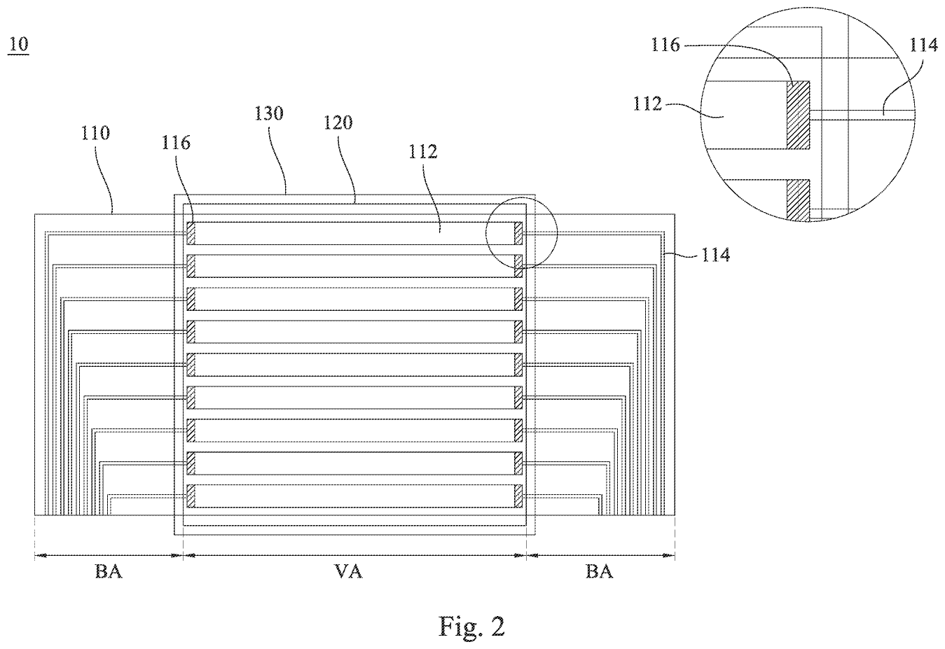

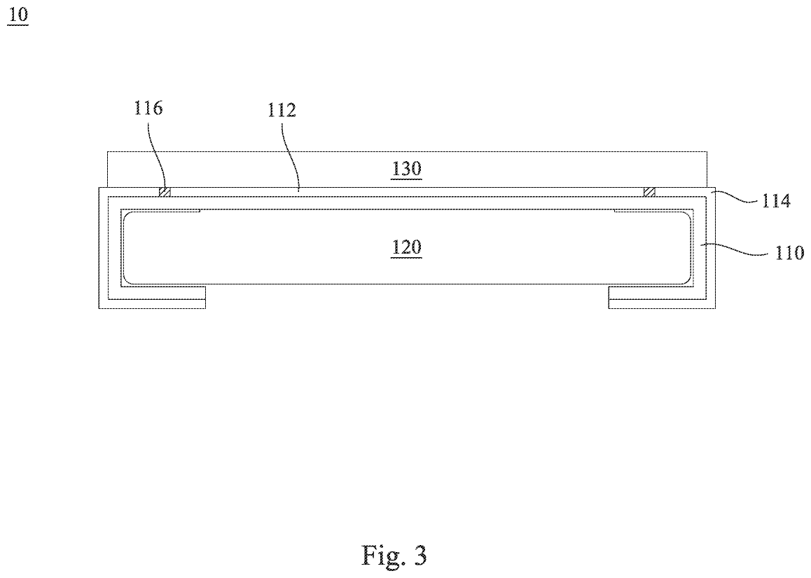

FIG. 1 illustrates a schematic cross-section view of a touch panel 10 according to one comparative example of the present disclosure, in which a flexible film 110 is not bent. FIG. 2 illustrates a schematic top view of a circuit design of the touch panel 10 according to one comparative example of the present disclosure. FIG. 3 illustrates a cross-section schematic view of the touch panel 10 according to one comparative example of the present disclosure, in which the flexible film 110 has been bent. Referring to FIGS. 1, 2, and 3, the touch panel 10 includes a flexible film 110, a display module 120, and a transparent cover 130. To be specific, the flexible film 110 is disposed between the display module 120 and the transparent cover 130. In order to meet the narrow frame design of the touch panel, the flexible film 110 of the touch panel 10 is extended and bent downward to the bottom of the display module 120, as shown in FIG. 3.

In some embodiments, the touch panel 10 is used to receive user's touch and converts the information contained in the user's touch into a touch signal, thereby transmitting the touch signal to the motherboard of the display module 120 and other processing devices for signal analysis. The flexible film 110 has the advantage of high transparency, so that the light containing image information emitted by the touch panel 10 passes through the transparent cover 130 and is transmitted to the user. In some embodiments, the flexible film 110 may include nylon, polyethylene, polypropylene, polycarbonate, polyurethane, polytetrafluoroethylene, polyethylene terephthalate, methyl methacrylate, polystyrene, or polyvinyl chloride, but the disclosure is not limited thereto.

As shown in FIG. 2, the flexible film 110 has a visible area VA and a bending area BA located at both ends of the visible area VA. In the present disclosure, it is noted that the area where the flexible film 110 overlaps the display module 120 is defined as the visible area VA, and the area where the flexible film 110 does not overlap the display module 120 is defined as the bending area BA. More specifically, a circuit design on the flexible film 110 includes an electrode pattern 112 and a connecting circuit 114. The electrode pattern 112 is disposed in the visible area VA of the flexible film 110, and the connecting circuit 114 is disposed in the bending area BA of the flexible film 110. Generally speaking, a contact pad 116 is provided and disposed at a junction of the electrode pattern 112 and the connecting circuit 114. However, the problem of the connecting circuit being broken or the contact pad 116 falling off easily occurs during the bending process of the flexible film 110, resulting in poor product yield.

In order to avoid the problem of poor product yield due to disconnection of the flexible film during the bending process, the present disclosure provides multiple circuit design embodiments that can solve the aforementioned problem. In order to facilitate the comparison with the aforementioned embodiments and simplify the description, the same reference numbers are used in the following embodiments to refer to the same or like parts. Also, the differences between embodiments are discussed below and similar parts will not be repeated.

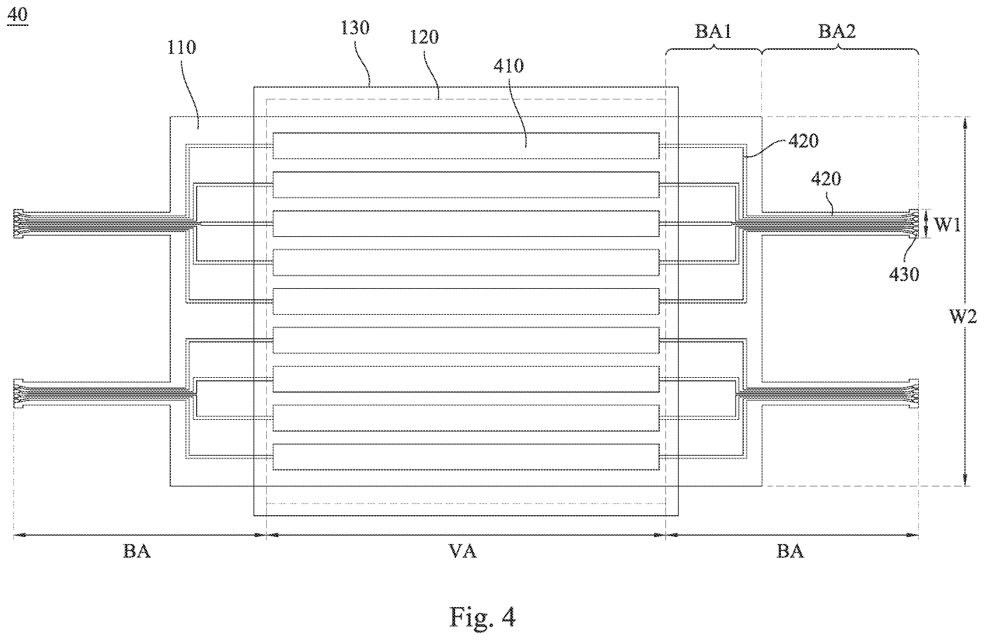

FIG. 4 illustrates a schematic top view of a circuit design 40 according to one embodiment of the present disclosure. As shown in FIG. 4, the circuit design 40 includes a flexible film 110, an electrode pattern 410, and a connecting circuit 420. To be specific, the flexible film 110 has a visible area VA and a bending area BA, and the flexible film 110 further includes an external conductive connection 430. The electrode pattern 410 is disposed in the visible area VA of the flexible film 110. In some embodiments, the type of the electrode pattern 410 can be designed according to the input principle of the touch panel (for example, capacitive type, resistive type, and pressure type). In one embodiment, the electrode pattern 410 includes a silver nanowire (SNW). It can be understood that the silver nanowire has the characteristics of bending resistance; therefore, in the subsequent bending process of the flexible film 110, the problem of wire breakage is unlikely to occur. In addition, the silver nanowire has better electrical conductivity and light transmittance. In some embodiments, a silver nanowire ink material including the silver nanowire can be coated on a flexible transparent film, and then a patterning process is used to manufacture the flexible film 110 having the electrode pattern 410 with the silver nanowire.

Referring to FIG. 4, the connecting circuit 420 is electrically connected to the electrode pattern 410 and disposed in the bending area BA of the flexible film 110. More specifically, the bending area BA has a first portion BA1 and a second portion BA2. The first portion BA1 is disposed between the visible area VA and the second portion BA2, and a width W1 of one end of the second portion BA2 adjacent to the first portion BA1 is smaller than a width W2 of the first portion BA1. It is noted that this embodiment does not need to additionally connect a flexible print circuit board (FCP). By lengthening the flexible film 110 and cutting the flexible film 110 into a shape that can enable the flexible film 110 to replace the flexible print circuit board, the process of bonding the flexible print circuit board to the flexible film can be reduced (or eliminated), thereby improving the process yield of manufacturing the touch panel. In one embodiment, the connecting circuit 420 includes a silver nanowire (SNW). It can be understood that the silver nanowire has the characteristics of bending resistance; therefore, in the subsequent bending process of the flexible film 110, the problem of wire breakage is unlikely to occur. In addition, the silver nanowire has better electrical conductivity and light transmittance. It can be understood that the connecting circuit 420 may serve as an electrical bridge between the electrode pattern 410 and the external conductive connection 430.

Referring to FIG. 4, the external conductive connection 430 is electrically connected to the connecting circuit 420 and disposed at another end of the second portion BA2. In one embodiment, the external conductive connection 430 includes a silver nanowire (SNW). It can be understood that the silver nanowire has the characteristics of bending resistance; therefore, in the subsequent bending process of the flexible film 110, the problem of wire breakage is unlikely to occur. In addition, the silver nanowire has better electrical conductivity and light transmittance. It can be understood that the external conductive connection 430 is used to transmit the signal received by the electrode pattern 410 located in the visible area VA to the display module 120.

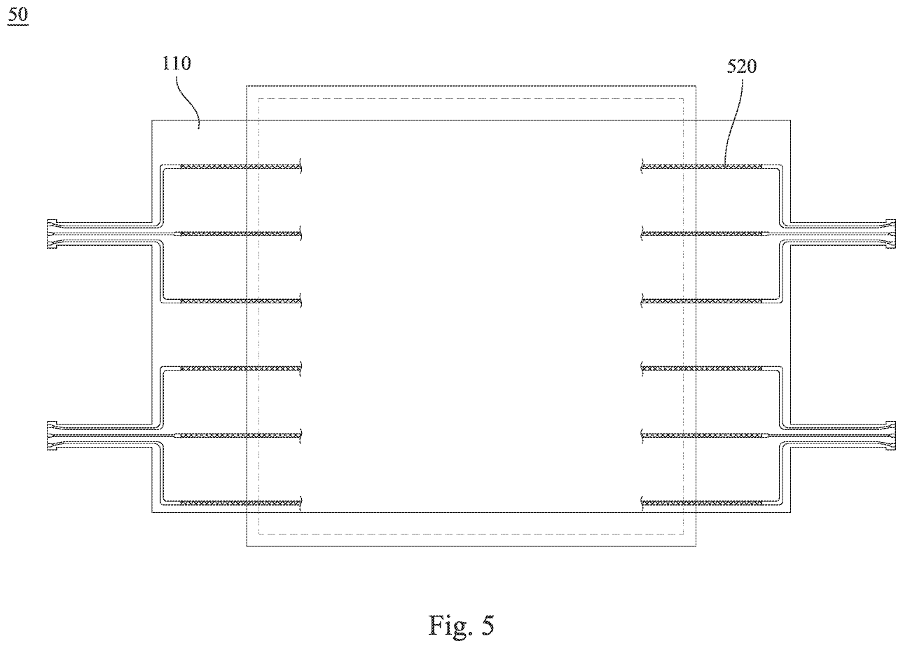

FIG. 5 illustrates a schematic top view of a circuit design 50 according to one embodiment of the present disclosure. The difference between the circuit design 50 shown in FIG. 5 and the circuit design 40 shown in FIG. 4 is that the connecting circuit 520 may be a mesh channel. More specifically, the mesh channel may be designed into various grid shapes, such as square, diamond, triangle, or a combination thereof, but the present disclosure is not limited thereto. This design can improve the fault tolerance of the circuit breakage of the flexible film 110 after bending.

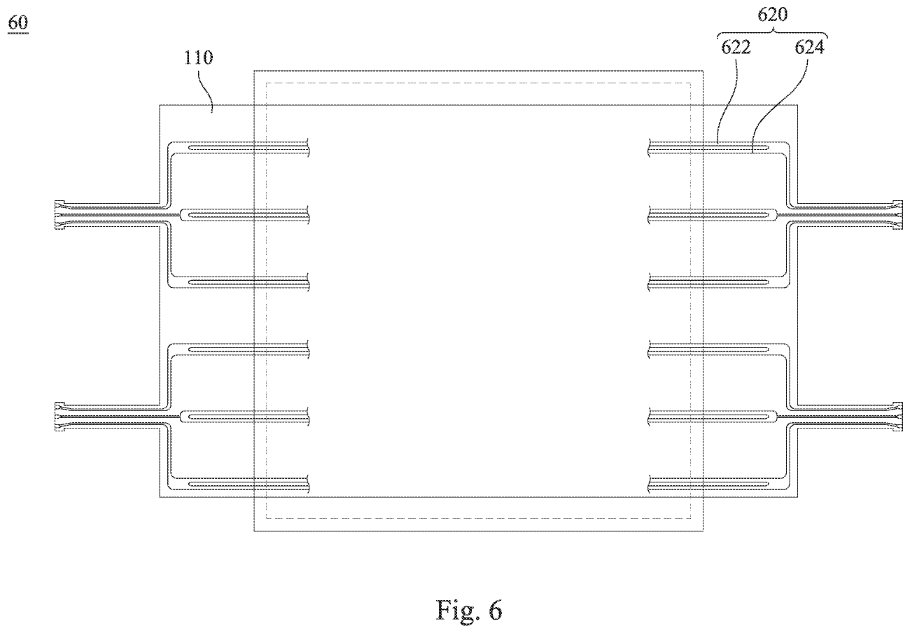

FIG. 6 illustrates a schematic top view of a circuit design 60 according to one embodiment of the present disclosure. The difference between the circuit design 60 shown in FIG. 6 and the circuit design 40 shown in FIG. 4 is that the connecting circuit 620 includes a first sub-circuit 622 and a second sub-circuit 624 disposed side by side. In other words, the first sub-circuit 622 and the second sub-circuit 624 are designed in parallel. This design can improve the fault tolerance of the circuit breakage of the flexible film 110 after bending. For example, if the first sub-circuit 622 is disconnected after the flexible film 110 is bent, the electrode pattern 410 can still be electrically connected to the external conductive connection 430 through the second sub-circuit 624. Although the connecting circuit 620 in FIG. 6 merely shows two sub-circuits 622/624, the number of sub-circuits included in the connecting circuit 620 may be three, four, five, and/or more in other alternative embodiments.

### Experimental Example: Circuit Breakage Risk and Product Yield Test

After the circuit design in the flexible film 110 shown in FIG. 2 of the comparative example, the circuit design 50 shown in FIG. 5 of one embodiment of the present disclosure, and the circuit design 60 shown in FIG. 6 of another embodiment of the present disclosure are used for bending, the results of the circuit breakage rate and product yield test were shown in Table 1 below.

TABLE 1

| | circuit breakage rate (%) | product yield (%) |
|---|---|---|
| comparative example | 5.0 | 95.0 |
| circuit design 50 | 2.5-1.0 | 97.5-99.0 |
| circuit design 60 | 2.5-1.0 | 97.5-99 |

It can be seen from Table 1 that compared with the circuit design of the comparative example shown in FIG. 2, the circuit designs 50/60 of the present disclosure can reduce the probability of the circuit breakage after the flexible film 110 is bent, and the product yield can be improved effectively.

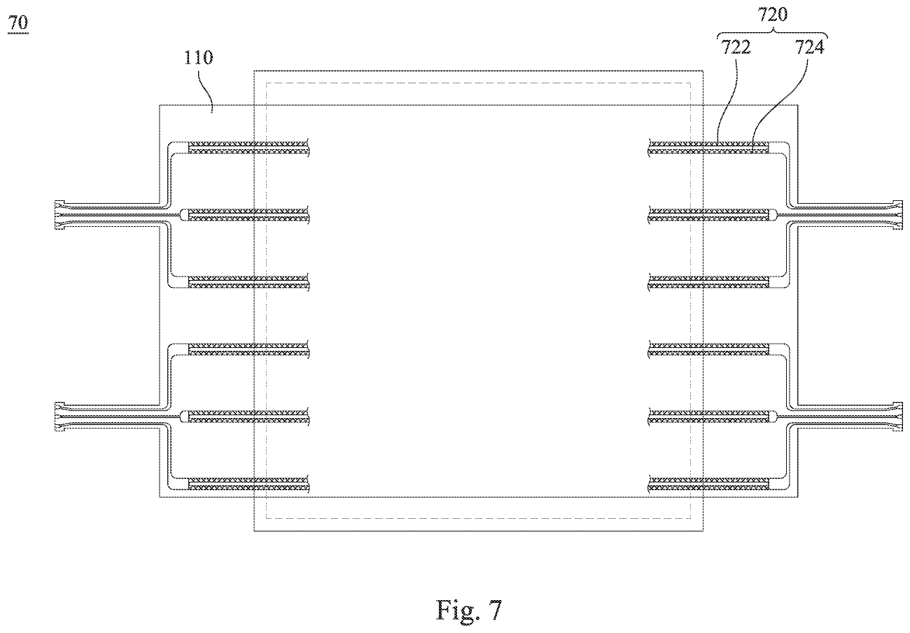

FIG. 7 illustrates a schematic top view of a circuit design 70 according to one embodiment of the present disclosure. The difference between the circuit design 70 shown in FIG. 7 and the circuit design 40 shown in FIG. 4 is that the connecting circuit 720 may further include a first sub-circuit 722 and a second sub-circuit 724 disposed side by side (or disposed in parallel). Each of the first sub-circuit 722 and the second sub-circuit 724 independently is a mesh channel. More specifically, each of the mesh channels may be designed into various grid shapes, such as square, diamond, triangle, or a combination thereof, but the present disclosure is not limited thereto. This design can improve the fault tolerance of the circuit breakage of the flexible film 110 after bending. Although the connecting circuit 720 in FIG. 7 merely shows two sub-circuits 722/724, the number of sub-circuits included in the connecting circuit 720 may be three, four, five, and/or more in other alternative embodiments.

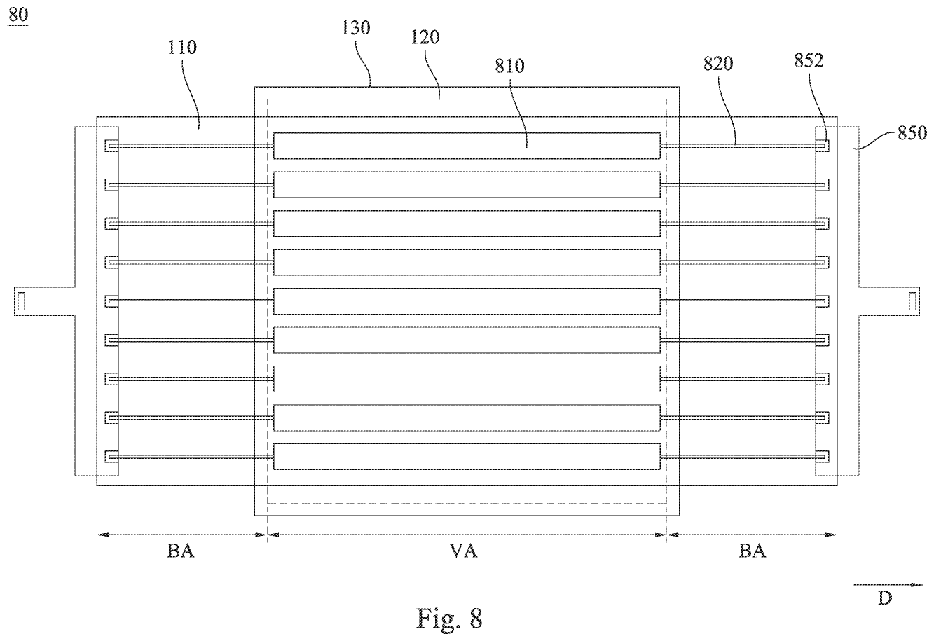

FIG. 8 illustrates a schematic top view of a circuit design 80 according to one embodiment of the present disclosure. As shown in FIG. 8, the circuit design 80 includes a flexible film 110, an electrode pattern 810, and a connecting circuit 820. To be specific, the flexible film 110 has a visible area VA and a bending area BA, and the electrode pattern 810 is disposed in the visible area VA of the flexible film 110. In one embodiment, the electrode pattern 810 includes a silver nanowire (SNW). It can be understood that the silver nanowire has the characteristics of bending resistance; therefore, in the subsequent bending process of the flexible film 110, the problem of wire breakage is unlikely to occur. In addition, the silver nanowire has better electrical conductivity and light transmittance. In some embodiments, a silver nanowire ink material including the silver nanowire can be coated on a flexible transparent film, and then a patterning process is used to manufacture the flexible film 110 having the electrode pattern 810 with the silver nanowire. For a more detailed description of the electrode pattern 810, please refer to the electrode pattern 410 in FIG. 4.

Referring to FIG. 8, the connecting circuit 820 is electrically connected to the electrode pattern 810 and disposed in the bending area BA of the flexible film 110. It is noted that the connecting circuit 820 is straight. More specifically, the connecting circuit 820 extends linearly from one end to the other end of the bending area BA along a direction D and does not include any bending part. In one embodiment, the connecting circuit 820 includes a silver nanowire (SNW). It can be understood that the silver nanowire has the characteristics of bending resistance; therefore, in the subsequent bending process of the flexible film 110, the problem of wire breakage is unlikely to occur. In addition, the silver nanowire has better electrical conductivity and light transmittance.

In some embodiments, the connecting circuit 820 may be a mesh channel. Although this embodiment is not shown in the figure, please refer to the connecting circuit 520 shown in FIG. 5 for more detail. More specifically, the mesh channel may be designed into various grid shapes, such as square, diamond, triangle, or a combination thereof, but the present disclosure is not limited thereto. This design can improve the fault tolerance of the circuit breakage of the flexible film 110 after bending.

In some embodiments, the connecting circuit 820 may further include a first sub-circuit and a second sub-circuit disposed side by side (or disposed in parallel). Although this embodiment is not shown in the figure, please refer to the connecting circuit 620 shown in FIG. 6 for more detail. It is noted that the number of sub-circuits included in the connecting circuit 820 in the present disclosure may include three, four, five, and/or more.

In some embodiments, the connecting circuit 820 may further include a first sub-circuit and a second sub-circuit disposed side by side (or disposed in parallel), each of which is independently a mesh channel. Although this embodiment is not shown in the figure, please refer to the connecting circuit 720 shown in FIG. 7 for more detail. It is noted that the number of sub-circuits included in the connecting circuit 820 in the present disclosure may include three, four, five, and/or more.

Referring to FIG. 8, in one embodiment, the circuit design 80 may further include a flexible printed circuit board 850 bonded to one end of the bending area BA far away from the visible area VA and electrically connected to the connecting circuit 820. More specifically, the flexible printed circuit board 850 has a solder pad 852 thereon corresponding to the connecting circuit 820. The connecting circuit 820 is directly bonded to the corresponding solder pad 852 on the flexible printed circuit board 850 by a lamination process. In some embodiments, multiple flexible printed circuit boards 850 may be used to electrically connect to the corresponding connecting circuit 820.

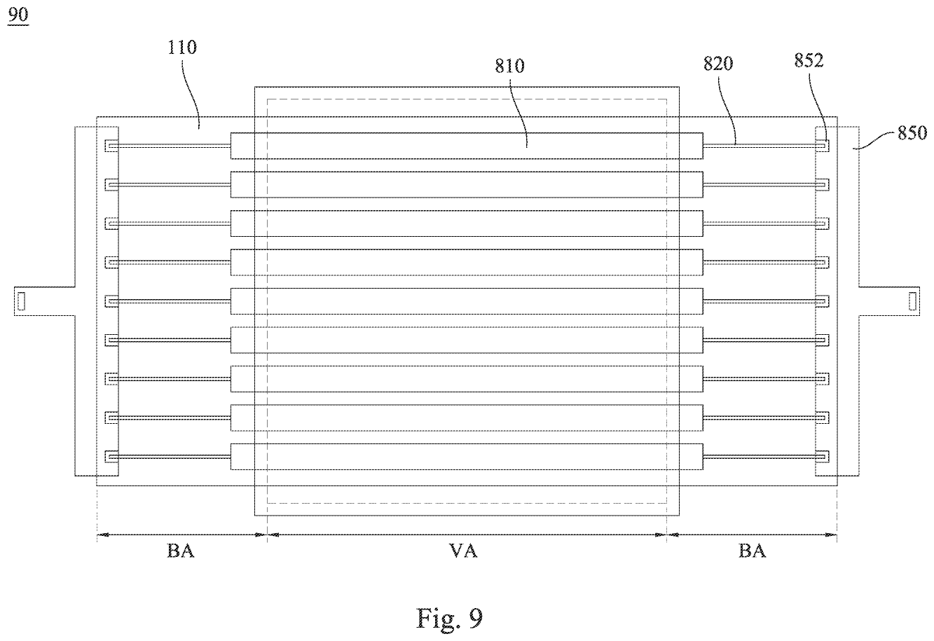

FIG. 9 illustrates a schematic top view of a circuit design 90 according to one embodiment of the present disclosure. The difference between the circuit design 90 shown in FIG. 9 and the circuit design 80 shown in FIG. 8 is that the electrode pattern 810 extends to (i.e., into) the bending area BA. This design can reduce the risk of circuit breakage of the flexible film 110 during the bending process.

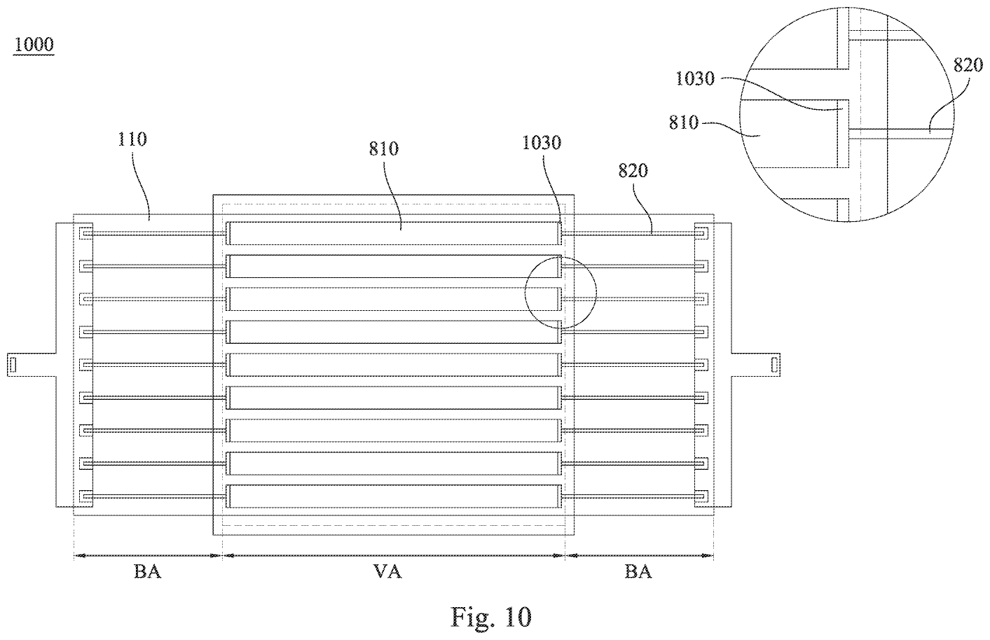

FIG. 10 illustrates a schematic top view of a circuit design 1000 according to one embodiment of the present disclosure. The difference between the circuit design 1000 shown in FIG. 10 and the circuit design 80 shown in FIG. 8 is that the circuit design 1000 further includes a silver paste pad 1030 disposed between the electrode pattern 810 and the connecting circuit 820 and in direct contact with the electrode pattern 810 and the connecting circuit 820.

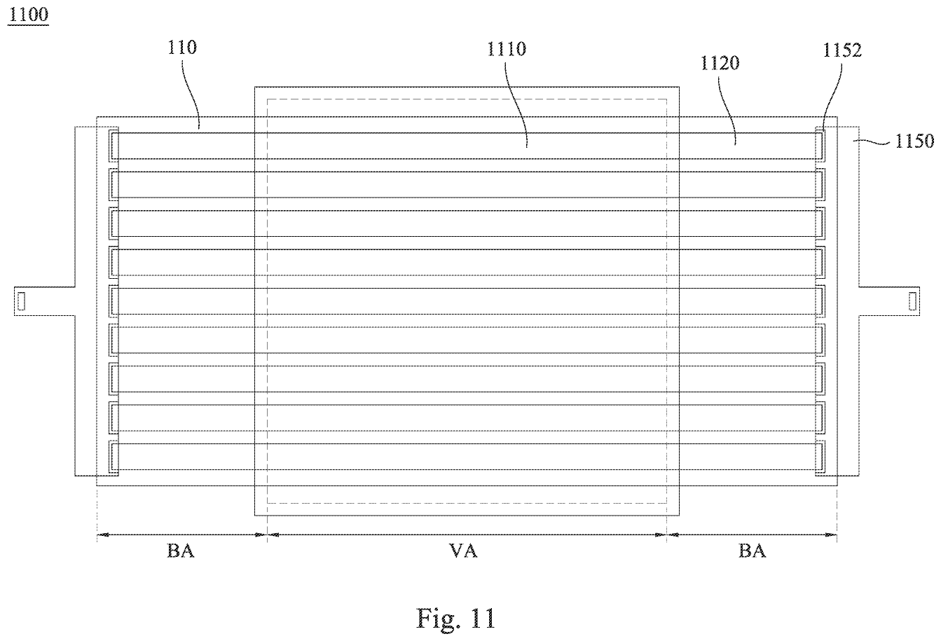

FIG. 11 illustrates a schematic top view of a circuit design 1100 according to one embodiment of the present disclosure. As shown in FIG. 11, the circuit design 1100 includes a flexible film 110, an electrode pattern 1110, and a connecting circuit 1120. To be specific, the flexible film 110 has a visible area VA and a bending area BA, and the electrode pattern 1110 is disposed in the visible area VA of the flexible film 110. In one embodiment, the electrode pattern 1110 includes a silver nanowire (SNW). It can be understood that the silver nanowire has the characteristics of bending resistance; therefore, in the subsequent bending process of the flexible film 110, the problem of wire breakage is unlikely to occur. In addition, the silver nanowire has better electrical conductivity and light transmittance. In some embodiments, a silver nanowire ink material including the silver nanowire can be coated on a flexible transparent film, and then a patterning process is used to manufacture the flexible film 110 having the electrode pattern 1110 with the silver nanowire. For a more detailed description of the electrode pattern 1110, please refer to the electrode pattern 410 in FIG. 4.

Referring to FIG. 11, the connecting circuit 1120 is electrically connected to the electrode pattern 1110 and disposed in the bending area BA of the flexible film 110. It is noted that the connecting circuit 1120 has the same circuit pattern as the electrode pattern 1110. In one embodiment, the electrode pattern 1110 and the connecting circuit 1120 are formed at the same time in the same process step. This design can reduce the risk of circuit breakage of the flexible film 110 during the bending process. In one embodiment, the connecting circuit 1120 includes a silver nanowire (SNW). It can be understood that the silver nanowire has the characteristics of bending resistance; therefore, in the subsequent bending process of the flexible film 110, the problem of wire breakage is unlikely to occur. In addition, the silver nanowire has better electrical conductivity and light transmittance.

Referring to FIG. 11, in one embodiment, the circuit design 1100 further includes a flexible printed circuit board 1150 bonded to one end of the bending area BA far away from the visible area VA and electrically connected to the connecting circuit 1120. More specifically, the flexible printed circuit board 1150 has a solder pad 1152 thereon corresponding to the connecting circuit 1120. The connecting circuit 1120 is directly bonded to the corresponding solder pad 1152 on the flexible printed circuit board 1150 by a lamination process. In some embodiments, multiple flexible printed circuit boards 1150 may be used to electrically connect to the corresponding connecting circuit 1120.

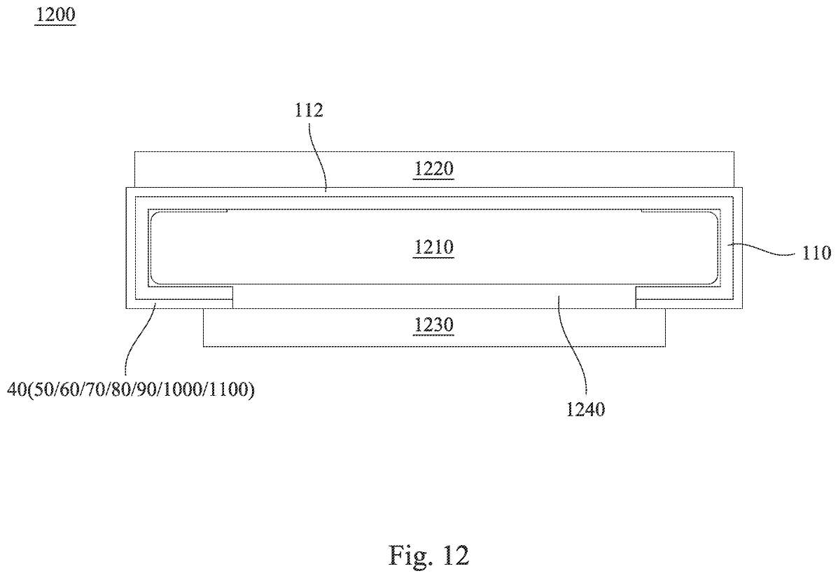

FIG. 12 illustrates a cross-section schematic view of a touch panel 1200 according to one embodiment of the present disclosure. The touch panel 1200 includes a liquid crystal display module 1210, the circuit design 40/50/60/70/80/90/1000/1100 previous discussed, a transparent cover 1220, and a circuit board 1230. In some embodiments, the liquid crystal display module 1210 may include a liquid crystal display panel (not shown) and a backlight module (not shown). Generally speaking, the liquid crystal display panel and the backlight module can be combined and fixed by a frame to form the liquid crystal display module 1210. In some embodiments, the backlight module includes elements such as an optical film set, a light guide plate, a light source set, and a reflective sheet.

As shown in FIG. 12, the circuit design 40/50/60/70/80/90/1000/1100 is disposed over the liquid crystal display module 1210. In some embodiments, the circuit design 40/50/60/70/80/90/1000/1100 disposed on the flexible film 110 is used to receive user's touch and converts the information contained in the user's touch into a touch signal, thereby transmitting the touch signal to the motherboard of the liquid crystal display module 1210 and other processing devices for signal analysis. Furthermore, the flexible film 110 has the advantage of high transparency, so that the light containing image information emitted by the touch panel 1200 passes through the transparent cover 1220 and is transmitted to the user. In some embodiments, the flexible film 110 may include nylon, polyethylene, polypropylene, polycarbonate, polyurethane, polytetrafluoroethylene, polyethylene terephthalate, methyl methacrylate, polystyrene, or polyvinyl chloride, but the disclosure is not limited thereto.

As shown in FIG. 12, the transparent cover 1220 is disposed over the circuit design 40/50/60/70/80/90/1000/1100. In some embodiments, the transparent cover 1220 may be a cover glass. In some embodiments, the transparent cover 1220 may include polyethylene terephthalate (PET), polyimide (PI), polyethylene naphthalatc (PEN), poly(ether sulfones) (PES), polyetheretherketone (PEEK), polycarbonate (PC), polypropylene (PP), polyamide (PA), or poly(methyl methacrylate) (PMMA), but the disclosure is not limited thereto.

As shown in FIG. 12, the circuit board 1230 is disposed below the liquid crystal display module 1210. To be specific, after the bending area BA of the flexible film 110 of the circuit design 40/50/60/70/80/90/1000/1100 is bent downward, the circuit design 40/50/60/70/80/90/1000/1100 located on the flexible film 110 is electrically connected to the circuit board 1230. More specifically, the circuit design 40/50/60/70/80/90/1000/1100 located on the flexible film 110 may be electrically connected to the circuit board 1230 by the external conductive connection 430 or the flexible printed circuit board 850/1150.

In some embodiments, the touch panel 1200 may further include an optical cement 1240 disposed between the liquid crystal display module 1210 and the circuit board 1230. The optical cement 1240 is used to increase the adhesion between the liquid crystal display module 1210 and the circuit board 1230.

In summary, the circuit design of the present disclosure can reduce the risk of circuit disconnection during the bending process of the flexible film, thereby increasing the product yield.

Although the present disclosure has been described in considerable detail with reference to certain embodiments thereof, other embodiments are possible. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A circuit design, comprising:
a flexible film comprising an external conductive connection and having a visible area and a bending area;
an electrode pattern disposed in the visible area of the flexible film; and
a connecting circuit electrically connected to the electrode pattern and disposed in the bending area of the flexible film, wherein the bending area has a first portion and a second portion, the first portion is located between the visible area and the second portion, a width of one end of the second portion connected to the first portion is smaller than a width of the first portion, a width of the flexible film underlying the second portion is smaller than a width of the flexible film underlying the first portion, and the external conductive connection is electrically connected to the connecting circuit and located at another end of the second portion.

2. The circuit design of claim 1, wherein each of the electrode pattern, the connecting circuit, and the external conductive connection independently comprises a silver nanowire.

3. The circuit design of claim 1, wherein the connecting circuit is a mesh channel.

4. The circuit design of claim 1, wherein the connecting circuit comprises a first sub-circuit and a second sub-circuit disposed side by side.

5. The circuit design of claim 4, wherein each of the first sub-circuit and the second sub-circuit independently is a mesh channel.

6. A circuit design, comprising:
a flexible film having a visible area and a bending area;
a plurality of electrode patterns disposed in the visible area of the flexible film; and
a plurality of connecting circuits electrically connected to a corresponding one of the plurality of electrode patterns and disposed in the bending area of the flexible film, wherein each of the plurality of connecting circuits is straight.

7. The circuit design of claim 6, wherein each of the plurality of electrode patterns and each of the plurality of connecting circuits independently comprises a silver nanowire.

8. The circuit design of claim 6, further comprising a flexible printed circuit board bonded to one end of the bending area away from the visible area and electrically connected to the plurality of connecting circuits.

9. The circuit design of claim 6, wherein the plurality of electrode patterns extend to the bending area.

10. The circuit design of claim 6, further comprising a silver paste pad disposed between the plurality of electrode patterns and the plurality of connecting circuits and in direct contact with the plurality of electrode patterns and the plurality of connecting circuits.

11. The circuit design of claim 6, wherein the plurality of connecting circuits are mesh channels.

12. The circuit design of claim 6, wherein each of the plurality of connecting circuits comprises a first sub-circuit and a second sub-circuit disposed side by side.

13. The circuit design of claim 12, wherein each of the first sub-circuit and the second sub-circuit independently is a mesh channel.

14. A circuit design, comprising:
a flexible film having a visible area and a bending area;
an electrode pattern disposed in the visible area of the flexible film; and
a connecting circuit electrically connected to the electrode pattern and disposed in the bending area of the flexible film, wherein the connecting circuit has a circuit pattern that is the same as the electrode pattern such that a width of the connecting circuit is equal to a width of the electrode pattern.

15. The circuit design of claim 14, wherein each of the electrode pattern and the connecting circuit independently comprises a silver nanowire.

16. The circuit design of claim 14, further comprising a flexible printed circuit board bonded to one end of the bending area away from the visible area and electrically connected to the connecting circuit.

17. A touch panel, comprising:
a liquid crystal display module;
the circuit design of claim 1 disposed over the liquid crystal display module;
a transparent cover disposed over the circuit design; and
a circuit board disposed below the liquid crystal display module, wherein the bending area of the flexible film of the circuit design is bent downward, and the circuit design is electrically connected to the circuit board.

18. A touch panel, comprising:
a liquid crystal display module;
the circuit design of claim 6 disposed over the liquid crystal display module;
a transparent cover disposed over the circuit design; and
a circuit board disposed below the liquid crystal display module, wherein the bending area of the flexible film of the circuit design is bent downward, and the circuit design is electrically connected to the circuit board.

19. A touch panel, comprising:
a liquid crystal display module;
the circuit design of claim 14 disposed over the liquid crystal display module;
a transparent cover disposed over the circuit design; and
a circuit board disposed below the liquid crystal display module, wherein the bending area of the flexible film of the circuit design is bent downward, and the circuit design is electrically connected to the circuit board.

20. The circuit design of claim 1, wherein the flexible film underlying the second portion of the bending area is segmented into a plurality of segments.
